(19) United States
(12) Patent Application Publication
(10) Pub. No.: US 2025/0270482 A1
(43) Pub. Date: Aug. 28, 2025

(54) COMPOSITION, CLEANING METHOD USING THE SAME, AND METHOD OF MANUFACTURING SEMICONDUCTOR DEVICE BY USING THE COMPOSITION

(71) Applicant: Samsung Electronics Co., Ltd., Suwon-si (KR)

(72) Inventors: Byungjoon KANG, Suwon-si (KR); Sungmin KIM, Suwon-si (KR); Insun PARK, Suwon-si (KR); Kum Hee LEE, Suwon-si (KR); Cheol HAM, Suwon-si (KR); Kyuyoung HWANG, Suwon-si (KR); Jina KIM, Suwon-si (KR)

(73) Assignee: Samsung Electronics Co., Ltd., Suwon-si (KR)

(21) Appl. No.: 19/007,942

(22) Filed: Jan. 2, 2025

(30) Foreign Application Priority Data
Feb. 28, 2024 (KR) 10-2024-0029229

(51) Int. Cl. C11D 7/34; C11D 7/08; C11D 7/10; C11D 7/50

(52) U.S. Cl. CPC C11D 7/34; C11D 7/08; C11D 7/10; C11D 7/50; C11D 2111/22

(57) ABSTRACT

A composition may include a fluorine-containing compound, an oxidizing agent, a titanium etching inhibitor, and a solvent. The titanium etching inhibitor may include a compound represented by Formula 1:

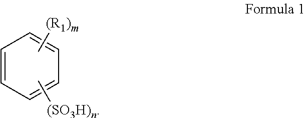

A description of Formula 1 is provided in the present specification. A cleaning method may use the composition. A method of manufacturing a semiconductor device may use the composition.

### CROSS-REFERENCE TO RELATED APPLICATION

This application is based on and claims priority under 35 U.S.C. § 119 to Korean Patent Application No. 10-2024-0029229, filed on Feb. 28, 2024, in the Korean Intellectual Property Office, the disclosure of which is incorporated by reference herein in its entirety.

### BACKGROUND

### 1. Field

The disclosure relates to a composition, a cleaning method using the same, and a method of manufacturing a semiconductor device by using the composition.

### 2. Description of the Related Art

To satisfy the demands of consumers for semiconductor devices with excellent performance and low cost, there is a need for increased integration and improved reliability of semiconductor devices. As the integration of semiconductor devices increases, damage to components of the semiconductor devices has a greater effect on the reliability and electrical characteristics of the semiconductor devices during a manufacturing process thereof. In particular, in manufacturing processes of semiconductor devices, surface residue generated as a result of surface treatment (e.g., dry etching, etc.) of a film (e.g., a metal-containing film) may cause exfoliation of a film, which may be additionally laminated, or the generation of cracks. In addition, various chemical substances may be absorbed by or adhered onto the surface residue, causing a phenomenon in which a film existing around the surface residue is additionally etched. Therefore, there is a continuously increasing need for an effective cleaning process and cleaning composition, which can remove substantially all of the surface residue, and at the same time does not cause defects in products including a metal-containing film and does not damage the surface of a target film to be cleaned.

### SUMMARY

Provided are a cleaning composition, which can provide excellent detergency, and at the same time, does not damage a target film, e.g., a titanium-containing film, to be cleaned, a cleaning method by using the same, and a method of manufacturing a semiconductor device by using the cleaning composition.

Additional aspects will be set forth in part in the description which follows and, in part, will be apparent from the description, or may be learned by practice of the presented embodiments of the disclosure.

According to an example embodiment, a composition may include
a fluorine-containing compound, an oxidizing agent, and a titanium etching inhibitor,
wherein the titanium etching inhibitor may include a compound represented by Formula 1:

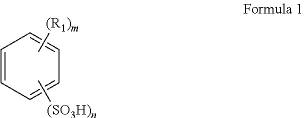

wherein, in Formula 1,
R₁ may be a C₂-C₆₀ alkyl group unsubstituted or substituted with deuterium, *—F, *—Cl, *—Br, *—I, *—OH, *—SH, *—NH₂, *—C(═O)H, *—C(═S)H, *—C(═O)—OH, *—C(═S)—OH, *—C(═O)—SH, *—C(═S)—SH, *—C(═O)—(NH₂), *—C(═S)—(NH₂), *—NH—C(═O)—(NH₂), *—NH—C(═S)—(NH₂), a C₁-C₆₀ alkoxy group, a phenyl group, or any combination thereof,
m and n each independently may be an integer from 1 to 5, and
a sum of m and n may be 2 to 6.

According to an example embodiment, a cleaning method may include preparing a substrate including a titanium-containing film and a residue, and cleaning the titanium-containing film by using the composition to remove at least a portion of the residue.

According to an example embodiment, a method of manufacturing a semiconductor device may include preparing a substrate including a titanium-containing film and a residue, cleaning the titanium-containing film by using the composition to remove at least a portion of the residue, and preparing a semiconductor device by performing a subsequent manufacturing process(es).

### BRIEF DESCRIPTION OF THE DRAWINGS

The above and other aspects, features, and advantages of certain embodiments will be more apparent from the following description taken in conjunction with the accompanying drawings, in which:

FIG. 1 illustrates a process flow diagram of an embodiment of a method of manufacturing a semiconductor device; and

FIGS. 2 and 3 are diagrams briefly explaining an embodiment of a cleaning method.

### DETAILED DESCRIPTION

Reference will now be made in detail to embodiments, and the present embodiments may have different forms and should not be construed as being limited to the descriptions set forth herein. Accordingly, the embodiments are merely described below to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

### Target Film to be Cleaned

A target film to be cleaned may include a titanium-containing film.

The titanium-containing film may include, in addition to titanium, an alkali metal (e.g., sodium (Na), potassium (K), rubidium (Rb), cesium (Cs), etc.), an alkaline earth metal (e.g., beryllium (Be), magnesium (Mg), calcium (Ca), strontium (Sr), barium (Ba), etc.), a lanthanide metal (e.g., lanthanum (La), europium (Eu), terbium (Tb), ytterbium (Yb), etc.), a transition metal (e.g., scandium (Sc), yttrium (Y), zirconium (Zr), hafnium (Hf), vanadium (V), niobium (Nb), tantalum (Ta), chromium (Cr), molybdenum (Mo), tungsten (W), manganese (Mn), iron (Fe), ruthenium (Ru), osmium (Os), cobalt (Co), rhodium (Rh), nickel (Ni), copper (Cu), silver (Ag), zinc (Zn), etc.), a post-transition metal (e.g., aluminum (Al), gallium (Ga), indium (In), thallium (TI), tin (Sn), bismuth (Bi), etc.), or any combination thereof.

In an embodiment, the titanium-containing film may further include, in addition titanium, In, Al, Cu, W, Co, La, Sc, Ga, Zn, Hf, Mo, or any combination thereof.

For example, the titanium-containing film may include titanium nitride.

The titanium nitride may further include In, Al, Cu, W, Co, La, Sc, Ga, Zn, Hf, Mo, or any combination thereof.

In one or more embodiments, the titanium-containing film may include i) titanium nitride, ii) titanium nitride further including In, Al, Cu, W, Co, La, Sc, Ga, Zn, Hf, Mo, or any combination thereof (e.g., TiAlN), or iii) a combination thereof.

In one or more embodiments, the titanium-containing film may further include metal oxide, metal oxynitride, or any combination thereof. For example, a metal included in the metal oxide may include Ti, Al, La, Sc, Ga, Hf, or any combination thereof.

In one or more embodiments, the titanium-containing film may further include, in addition to the aforementioned metal, a metalloid (e.g., boron (B), silicon (Si), germanium (Ge), arsenic (As), antimony (Sb), tellurium (Te), etc.), a non-metal (e.g., nitrogen (N), phosphorus (P), oxygen (O), sulfur (S), selenium (Se), etc.), or any combination thereof. For example, the titanium-containing film may further include silicon oxide.

The titanium-containing film may have a single-layer structure including at least one type of materials or a multi-layer structure or three-dimensional pattern structure including different materials from each other.

The titanium-containing film, which is a target film to be cleaned, may further include a residue.

The residue to be removed with the composition described herein may refer to a residue that is separated from the titanium-containing film after surface treatment (e.g., dry etching, etc.) of the target film to be cleaned, such as the titanium-containing film, and then generated on the surface of the titanium-containing film, or a residue that is derived from various films adjacent to the titanium-containing film.

In an embodiment, the residue may include a metal.

In one or more embodiments, the residue may include In, Al, Cu, W, Co, La, Sc, Ga, Zn, Hf, Mo, or any combination thereof.

### Composition

A composition may include a fluorine-containing compound, an oxidizing agent, and a titanium etching inhibitor.

In an embodiment, the composition may further include a solvent.

In an embodiment, the solvent may include water (e.g., deionized water).

In one or more embodiments, the solvent may include alcohol (e.g., 2-propanol).

### Fluorine-Containing Compound

The fluorine-containing compound refers to a compound containing ionic fluoride (F⁻) or covalently bonded fluorine.

The fluorine-containing compound may serve to oxidize and/or remove residues on a substrate including a target film to be cleaned.

For example, the fluorine-containing compound may include:
i) fluorine-containing acid (e.g., HF);
ii) a compound containing a B—F bond or a Si—F bond (e.g., tetrafluoroboric acid, hexafluorosilicic acid, hexafluorosilicate, etc.);
iii) H₂ZrF₆, H₂TiF₆, or HPF₆;
iv) a fluorinated compound containing an ammonium-based ion (e.g., N(R₁₁)(R₁₂)(R₁₃)(R₁₄)F, [N(R₁₁)(R₁₂)(R₁₃)(R₁₄)]₂TiF₆, etc.); or
v) any combination thereof,
wherein R₁₁ to R₁₄ may each independently be hydrogen, a C₁-C₁₀ alkyl group, or a fluorinated C₁-C₁₀ alkyl group.

In an embodiment, the fluorine-containing compound may include HF, tetrafluoroboric acid, hexafluorosilicic acid, H₂ZrF₆, H₂TiF₆, HPF₆, ammonium fluoride (NH₄F), tetramethylammonium fluoride, ammonium hexafluorosilicate, ammonium hexafluorotitanate, or any combination thereof.

In one or more embodiments, the fluorine-containing compound may include HF, ammonium fluoride (NH₄F), tetramethylammonium fluoride, or any combination thereof.

In one or more embodiments, the fluorine-containing compound may include HF.

The amount (weight) of the fluorine-containing compound may be, per 100 wt % of the composition, in a range of about 0.001 wt % to about 20 wt %, about 0.001 wt % to about 10 wt %, about 0.001 wt % to about 5 wt %, about 0.001 wt % to about 1 wt %, about 0.001 wt % to about 0.5 wt %, about 0.001 wt % to about 0.1 wt %, about 0.005 wt % to about 20 wt %, about 0.005 wt % to about 10 wt %, about 0.005 wt % to about 5 wt %, about 0.005 wt % to about 1 wt %, about 0.005 wt % to about 0.5 wt %, or about 0.005 wt % to about 0.1 wt %. When the amount of the fluorine-containing compound is within the ranges above, the residue cleaning performance of the composition may be improved.

### Oxidizing Agent

The oxidizing agent may serve to oxidize and/or remove residues on a substrate including a target film to be cleaned, along with the fluorine-containing compound.

The oxidizing agent may include:
i) hydrogen peroxide (H₂O₂);
ii) a metal-containing compound (e.g., FeCl₃, FeF₃, Fe(NO₃)₃, Sr(NO₃)₂, CoF₃, MnF₃, etc.);
iii) acid (e.g., periodic acid (H₅IO₆ or HIO₄), iodic acid (HIO₃), t-butyl hydroperoxide (—BuOOH, etc.);
iv) a vanadium-containing compound (e.g., vanadium (V) oxide, vanadium (IV,V) oxide, ammonium vanadate, etc.);
v) an ammonium polyatomic salt (e.g., ammonium peroxomonosulfate, ammonium chlorite (NH₄ClO₂), ammonium chlorate (NH₄ClO₃), ammonium iodate (NH₄IO₃), ammonium nitrate (NH₄NO₃), ammonium perborate (NH₄BO₃), ammonium perchlorate (NH₄ClO₄), ammonium periodate (NH₄IO₄), ammonium persulfate ((NH₄)₂S₂O₈), ammonium hypochlorite (NH₄ClO), ammonium tungstate ((NH₄)₁₀H₂(W₂O₇), etc.);
vi) a sodium polyatomic salt (e.g., sodium persulfate (Na₂S₂O₈), sodium hypochlorite (NaClO), sodium perborate, etc.);
vii) a potassium polyatomic salt (e.g., potassium iodate (KIO₃), potassium permanganate (KMnO₄), potassium persulfate, nitric acid (HNO₃), potassium persulfate (K₂S₂O₈), potassium hypochlorite (KClO, etc.);

viii) a tetraalkylammonium polyatomic salt (e.g., tetramethylammonium chlorite ((N(CH₃)₄)ClO₂), tetramethylammonium chlorate ((N(CH₃)₄)ClO₃), tetramethylammonium iodate ((N(CH₃)₄)IO₃), tetramethylammonium perborate ((N(CH₃)₄)BO₃), tetramethylammonium perchlorate ((N(CH₃)₄)ClO₄), tetramethylammonium periodate ((N(CH₃)₄)IO₄), tetramethylammonium persulfate ((N(CH₃)₄)S₂O₈), tetrabutylammonium, tetrabutylammonium peroxomonosulfate, etc.); or
ix) any combination thereof.

In an embodiment, the oxidizing agent may include HIO₄, HIO₃, NH₄IO₃, NH₄IO₄, or a combination thereof.

The amount (weight) of the oxidizing agent may be, per 100 wt % of the composition, in a range of about 0.0001 wt % to about 10 wt %, about 0.0001 wt % to about 5 wt %, about 0.0001 wt % to about 1 wt %, about 0.0001 wt % to about 0.1 wt %, about 0.0001 wt % to about 0.01 wt %, about 0.0005 wt % to about 10 wt %, about 0.0005 wt % to about 5 wt %, about 0.0005 wt % to about 1 wt %, about 0.0005 wt % to about 0.1 wt %, or about 0.0005 wt % to about 0.01 wt %. When the amount of the oxidizing agent is within the ranges above, the residue cleaning performance of the composition may be improved.

### Titanium Etching Inhibitor

The titanium etching inhibitor may serve to inhibit damage and/or etching of the titanium-containing film by forming a protective film on at least a portion of the surface of the titanium-containing film when cleaning the surface of a substrate including the titanium-containing film.

In the present specification, the titanium etching inhibitor refers to a material that inhibits etching of a titanium-containing compound, i.e., any compound including titanium.

For example, the titanium-containing compound may refer to i) titanium nitride, or ii) titanium nitride further including various types of metal (e.g., In, Al, La, Sc, Ga, Zn, Hf, or any combination thereof).

The titanium etching inhibitor may include a compound represented by Formula 1:

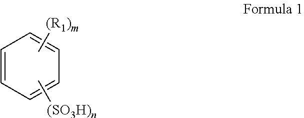

wherein R₁ in Formula 1 may include a C₂-C₆₀ alkyl group (e.g., a methyl group, an ethyl group, a propyl group, a butyl group, a pentyl group, a hexyl group, a heptyl group, an octyl group, a nonyl group, a decyl group, an undecyl group, a dodecyl group, a tridecyl group, a tetradecyl group, etc.) unsubstituted or substituted with deuterium, *—F, *—Cl, *—Br, *—I, *—OH, *—SH, *—NH₂, *—C(═O)H, *—C(═S)H, *—C(═O)—OH, *—C(═S)—OH, *—C(═O)—SH, *—C(═S)—SH, *—C(═O)—(NH₂), *—C(═S)—(NH₂), *—NH—C(═O)—(NH₂), *—NH—C(═S)—(NH₂), a C₁-C₆₀ alkoxy group, a phenyl group, or any combination thereof.

In an embodiment, R₁ in Formula 1 may include a C₂-C₂₀ alkyl group unsubstituted or substituted with *—F, —OH, *—SH, *—C(═O)H, *—C(═S)H, *—C(═O)—OH, *—C(═S)—OH, *—C(═O)—SH, *—C(═S)—SH, a C₁-C₁₀ alkoxy group, or any combination thereof.

In one or more embodiments, R₁ in Formula 1 may include a C₄-C₂₀ alkyl group (e.g., a butyl group, a pentyl group, a hexyl group, a heptyl group, an octyl group, a nonyl group, a decyl group, an undecyl group, a dodecyl group, a tridecyl group, a tetradecyl group, etc.) unsubstituted or substituted with *—F, —OH, *—SH, *—C(═O)H, *—C(═S)H, *—C(═O)—OH, *—C(═S)—OH, *—C(═O)—SH, *—C(═S)—SH, a C₁-C₁₀ alkoxy group, or any combination thereof.

In one or more embodiments, R₁ in Formula 1 may include a C₁₀-C₂₀ alkyl group (e.g., a decyl group, an undecyl group, a dodecyl group, a tridecyl group, a tetradecyl group, etc.) unsubstituted or substituted with *—F, —OH, *—SH, *—C(═O)H, *—C(═S)H, *—C(═O)—OH, *—C(═S)—OH, *—C(═O)—SH, *—C(═S)—SH, a C₁-C₁₀ alkoxy group, or any combination thereof.

In one or more embodiments, R₁ in Formula 1 may include a C₁₂ alkyl group unsubstituted or substituted with *—F, —OH, *—SH, *—C(═O)H, *—C(═S)H, *—C(═O)—OH, *—C(═S)—OH, *—C(═O)—SH, *—C(═S)—SH, a C₁-C₁₀ alkoxy group, or any combination thereof, such as a dodecyl group unsubstituted or substituted with *—F, —OH, *—SH, *—C(═O)H, *—C(═S)H, *—C(═O)—OH, *—C(═S)—OH, *—C(═O)—SH, *—C(═S)—SH, a C₁-C₁₀ alkoxy group, or any combination thereof.

The term “C₂-C₆₀ alkyl group, as used herein refers to a linear or branched alkyl group having 2 to 60 carbon atoms.

In Formula 1, m and n may each independently be an integer from 1 to 5, and the sum of m and n may be 2 to 6.

For example, in Formula 1, m may be 1 or 2, and n may be 1.

In an embodiment, the titanium etching inhibitor may include one of compounds represented by Formulae 1(1) to 1(6) or a combination thereof:

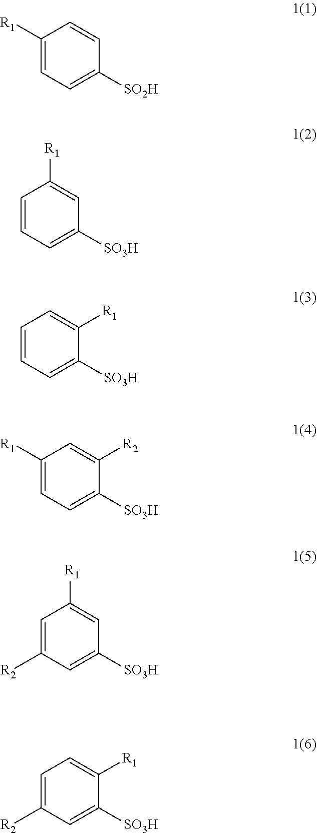

wherein, in Formulae 1(1) to 1(6),
R₁ is the same as defined herein, and
R₂ is the same as described in connection with R₁.

For example, in Formulae 1(1) to 1(6), R₁ and R₂ each independently may include a C₂-C₆₀ alkyl group (e.g., a methyl group, an ethyl group, a propyl group, a butyl group, a pentyl group, a hexyl group, a heptyl group, an octyl group, a nonyl group, a decyl group, an undecyl group, a dodecyl group, a tridecyl group, a tetradecyl group, etc.) unsubstituted or substituted with deuterium, *—F, *—Cl, *—Br, *—I, *—OH, *—SH, *—NH₂, *—C(═O)H, *—C(═S)H, *—C(═O)—OH, *—C(═S)—OH, *—C(═O)—SH, *—C(═S)—SH, *—C(═O)—(NH₂), *—C(═S)—(NH₂), *—NH—C(═O)—(NH₂), *—NH—C(═S)—(NH₂), a C₁-C₆₀ alkoxy group, a phenyl group, or any combination thereof.

In one or more embodiments, the titanium etching inhibitor may include at least one of 4-dodecylbenzenesulfonic acid (4-DBA) and m-tert-butylbenzenesulfonic acid.

The amount (weight) of the titanium etching inhibitor may be, per 100 wt % of the composition, in a range of about 0.01 wt % to about 20 wt %, about 0.01 wt % to about 10 wt %, about 0.01 wt % to about 5 wt %, about 0.01 wt % to about 3 wt %, about 0.1 wt % to about 20 wt %, about 0.1 wt % to about 10 wt %, about 0.1 wt % to about 5 wt %, or about 0.1 wt % to about 3 wt %. When the amount of the titanium etching inhibitor is within the ranges above, a protective film may be effectively formed over the titanium-containing film so that the etching and/or cleaning of the titanium-containing compound included in the titanium-containing film may be substantially limited and/or prevented during a cleaning process.

In one or more embodiments, in the composition, the amount of the fluorine-containing compound may be, per 100 wt % of the composition, in a range of about 0.005 wt % to about 0.5 wt %, amount of the oxidizing agent may be, per 100 wt % of the composition in a range of about 0.0005 wt % to about 0.01 wt %, and the amount of the titanium etching inhibitor may be, per 100 wt % of the composition, in a range of about 0.1 wt % to about 3 wt %. The fluorine-containing compound may include HF, and the oxidizing agent may include HIO₄, HIO₃, NH₄IO₃, NH₄IO₄, or any combination thereof.

The composition may further include a pH adjustor. The pH adjustor may include, for example, ammonium hydroxide (NH₄OH), ammonium hydroxide substituted with at least one C₁-C₂₀ alkyl group (e.g., N(CH₃)₄OH), methylsulfonic acid, or any combination thereof.

The amount (weight) of the pH adjustor may be, per 100 wt % of the composition, in a range of about 0.01 wt % to about 20 wt %, about 0.01 wt % to about 10 wt %, about 0.01 wt % to about 5 wt %, about 0.1 wt % to about 20 wt %, about 0.1 wt % to about 10 wt %, about 0.1 wt % to about 5 wt %, about 1 wt % to about 20 wt %, about 1 wt % to about 10 wt %, or about 1 wt % to about 5 wt %. When the amount of the pH adjustor is satisfied with the ranges above, the pH of the composition may be maintained at an appropriate level. For example, the pH of the composition may be 8 or less, for example, in a range of about 0 to about 2.

### Cleaning Method and Method of Manufacturing Semiconductor Device

When a titanium-containing film having a residue on a surface thereof is cleaned by using the aforementioned composition, the damage and/or etching of the titanium-containing film may substantially be limited and/or prevented due to the titanium etching inhibitor included in the composition, and at the same time, the residue may be effectively removed due to the fluorine-containing compound and the oxidizing agent included in the composition.

Thus, another aspect provides a cleaning method includes:
preparing a substrate including a titanium-containing film and a residue; and
cleaning the titanium-containing film by using the composition to remove at least a portion of the residue.

The titanium-containing film and the residue are each the same herein.

For example, the titanium-containing film may include i) titanium nitride, ii) titanium nitride further including In, Al, Cu, W, Co, La, Sc, Ga, Zn, Hf, Mo, or any combination thereof, or iii) a combination thereof.

In one or more embodiments, the residue may include In, Al, Cu, W, Co, La, Sc, Ga, Zn, Hf, Mo, or any combination thereof.

Since the composition includes the aforementioned titanium etching inhibitor, the titanium-containing film may not be substantially etched during a cleaning process.

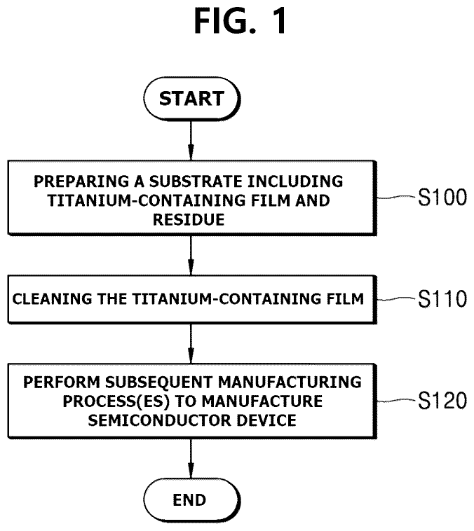

FIG. 1 illustrates a process flow diagram of an embodiment of a method of manufacturing a semiconductor device.

Referring to FIG. 1, according to an example embodiment of the disclosure, a method of manufacturing a semiconductor device may include:
preparing a substrate including a titanium-containing film and a residue (S100);
cleaning the titanium-containing film by using the composition to remove at least a portion of the residue (S110); and
preparing a semiconductor device by performing a subsequent manufacturing process(es) (S120).

For the reasons described above, a high-quality semiconductor device may be manufactured by using the composition because the titanium-containing film may not be substantially damaged and/or etched during a cleaning process and the residue on the surface of the titanium-containing film may be effectively removed.

Meanwhile, the cleaning method and the method of manufacturing the semiconductor device may each further include cleaning the titanium-containing film (and, optionally, a substrate provided with the titanium-containing film) by using an additional solvent, and optionally, may further include drying the titanium-containing film (and, optionally, a substrate provided with the titanium-containing film) followed by removing the additional solvent.

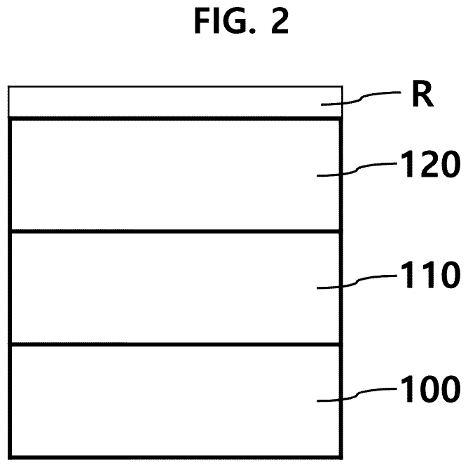

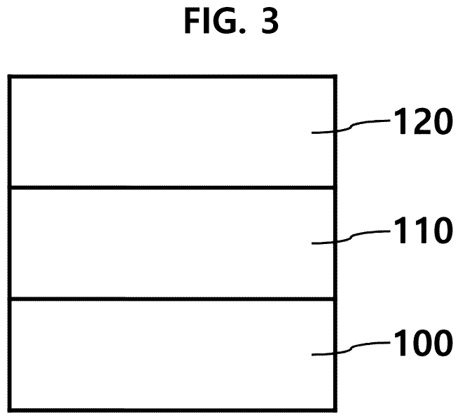

FIGS. 2 and 3 are diagrams briefly explaining an embodiment of a cleaning method.

Referring to FIGS. 1 and 2, a substrate 100, on which a titanium-containing film 120 and a residue R, is prepared (S100). An intermediate layer 110 may be arranged between the substrate 100 and the titanium-containing film 120. Although not shown in FIG. 2, circuitry elements (for example, transistor gates, metal lines), impurity regions, and semiconductor layers may be arranged within the substrate 100, on top of the substrate 100, and/or between the substrate 100 and the intermediate layer 110, and/or between the substrate 100 and the titanium-containing film 120. According to an embodiment, the titanium-containing film 120 may be arranged directly on the substrate 100, and the intermediate layer 110 may be omitted.

The titanium-containing film 120 may include i) titanium nitride, ii) titanium nitride further including In, Al, Cu, W, Co, La, Sc, Ga, Zn, Hf, Mo, or any combination thereof (e.g., TiAlN), or iii) a combination thereof.

The residue R may include indium (In), aluminum (AI), copper (Cu), tungsten (W), cobalt (Co), lanthanum (La), scandium (Sc), gallium (Ga), zinc (Zn), hafnium (Hf), molybdenum (Mo), or any combination thereof.

Referring to FIG. 3, a process of cleaning the titanium-containing film 120 may be performed and may include using the composition to remove at least a portion of the residue R. As shown in FIG. 3, the composition may remove all of the residue R. Alternatively, the composition may remove a portion of the residue R. The titanium-containing film 120 may be substantially not etched during the cleaning.

Hereinafter, one or more example embodiments will be described in further detail with reference to the following examples and comparative examples. These examples and comparative examples are not intended to limit the scope of inventive concepts.

### Example 1 and Comparative Example A

By mixing materials listed in Table 1, compositions of Example 1 and Comparative Example A were prepared. In each composition, the amount of a fluorine-containing compound was 0.01 wt %, the amount of an oxidizing agent was 0.001 wt %, the amount of a titanium etching inhibitor was 1 wt %, the amount of a pH adjustor was 4 wt %, and the remaining of each composition corresponded to water (deionized water), and the pH of each composition was about 1.

### Evaluation Example 1

The composition of Example 1 was added to two beakers and heated to a temperature of 70° C. Then, a titanium nitride (TiN) film specimen having a size of 1 cm×1 cm and a molybdenum (Mo) film specimen having a size of 1 cm×1 cm were immersed in each beaker for 5 minutes. The thicknesses of the TiN film and the Mo film were measured by using an ellipsometer (M-2000, J.A.Woolam), a four-point resistivity meter, and X-ray fluorescence (XRF), to evaluate the etching rate for the TiN film (ER, A/min) and the etching rate for the Mo film (Mo ER, A/min) of the composition of Example 1. Subsequently, by dividing the etching rate for the TiN film by the etching rate for the Mo film, the R(TiN/Mo) of the composition of Example 1 was evaluated, and the results are summarized in Table 1.

The same test was repeated by using the composition of Comparative Example A, and the results are summarized in Table 1.

TABLE 1

| | Fluorine- | | Titanium | | | | |
|---|---|---|---|---|---|---|---|
| | containing | Oxidizing | etching | pH | TiN ER | Mo ER | R |
| | compound | agent | inhibitor | adjustor | (Å/min) | (Å/min) | (TiN/Mo) |
| Example | HF | Periodic | 4- | Methyl- | 0 | 17.0 | 0 |
| 1 | | acid | dodecylbenzene- | sulfonic | | | |
| | | (HIO₄) | sulfonic | acid | | | |
| | | | acid | | | | |
| | | | (4-DBA) | | | | |
| Comparative | HF | Periodic | p- | Methyl- | 69.1 | 14 | 4.94 |
| Example | | acid | toluenesulfonic | sulfonic | | | |
| A | | | acid | acid | | | |

Referring to Table 1, it was confirmed that the composition of Example 1 had performance of inhibiting etching of the titanium nitride film, whereas the composition of Comparative Example A did not have performance of inhibiting etching of the titanium nitride film.

According to the one or more embodiments, a composition has excellent performance of removing surface residues, and at the same time, does not cause a damage a surface of a target film to be cleaned, e.g., a titanium-containing film, and thus the surface of a target film to be cleaned may be effectively cleaned by using the composition, and accordingly, a high-performance semiconductor device may be manufactured.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A composition comprising:
a fluorine-containing compound, an oxidizing agent, and a titanium etching inhibitor,
wherein the titanium etching inhibitor comprises a compound represented by Formula 1: 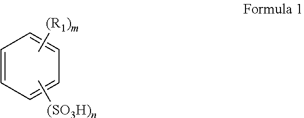
wherein, in Formula 1,
R₁ is a C₂-C₆₀ alkyl group unsubstituted or substituted with deuterium, *—F, *—C, *—Br, *—I, *—OH, *—SH, *—NH₂, *—C(═O)H, *—C(═S)H, *—C(═O)—OH, *—C(═S)—OH, *—C(═O)—SH, *—C(═S)—SH, *—C(═O)—(NH₂), *—C(═S)—(NH₂), *—NH—C(═O)—(NH₂), *—NH—C(═S)—(NH₂), a C₁-C₆₀ alkoxy group, a phenyl group, or any combination thereof,
m and n are each independently an integer from 1 to 5, and
a sum of m and n is 2 to 6.

2. The composition of claim 1, wherein
the fluorine-containing compound comprises HF, ammonium fluoride (NH₄F), tetramethylammonium fluoride, or any combination thereof.

3. The composition of claim 1, wherein the fluorine-containing compound comprises HF.

4. The composition of claim 1, wherein
an amount of the fluorine-containing compound is in a range of about 0.001 wt % to about 20 wt %, per 100 wt % of the composition.

5. The composition of claim 1, wherein the oxidizing agent comprises HIO₄, HIO₃, NH₄IO₃, NH₄IO₄, or any combination thereof.

6. The composition of claim 1, wherein an amount of the oxidizing agent is in a range of about 0.0001 wt % to about 10 wt %, per 100 wt % of the composition.

7. The composition of claim 1, wherein R₁ in Formula 1 comprises a C₄-C₂₀ alkyl group unsubstituted or substituted with *—F, —OH, *—SH, *—C(═O)H, *—C(═S)H, *—C(═O)—OH, *—C(═S)—OH, *—C(═O)—SH, *—C(═S)—SH, a C₁-C₁₀ alkoxy group, or any combination thereof.

8. The composition of claim 1, wherein R₁ in Formula 1 comprises a C₁₀-C₂₀ alkyl group unsubstituted or substituted with *—F, —OH, *—SH, *—C(═O)H, *—C(═S)H, *—C(═O)—OH, *—C(═S)—OH, *—C(═O)—SH, *—C(═S)—SH, a C₁-C₁₀ alkoxy group, or any combination thereof.

9. The composition of claim 1, wherein
in Formula 1,
m is 1 or 2, and
n is 1.

10. The composition of claim 1, wherein the titanium etching inhibitor comprises one of compounds represented by Formulae 1(1) to 1(6) or a combination thereof: 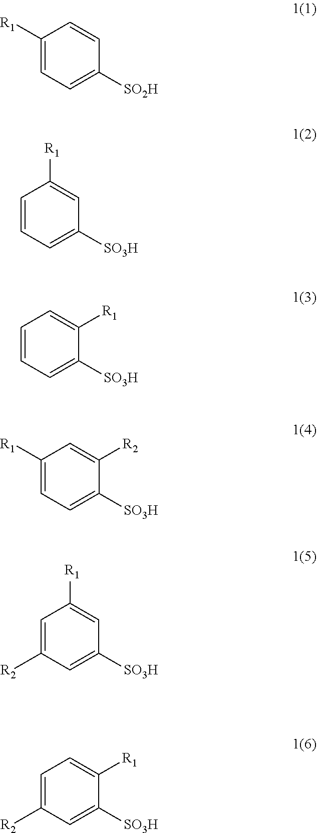
wherein, in Formulae 1(1) to 1(6),
R₁ and R₂ each independently are a C₂-C₆₀ alkyl group unsubstituted or substituted with deuterium, *—F, *—Cl, *—Br, *—I, *—OH, *—SH, *—NH₂, *—C(═O)H, *—C(═S)H, *—C(═O)—OH, *—C(═S)—OH, *—C(═O)—SH, *—C(═S)—SH, *—C(═O)—(NH₂), *—C(═S)—(NH₂), *—NH—C(═O)—(NH₂), *—NH—C(═S)—(NH₂), a C₁-C₆₀ alkoxy group, a phenyl group, or any combination thereof.

11. The composition of claim 1, wherein the titanium etching inhibitor comprises at least one of 4-dodecylbenzenesulfonic acid and m-tert-butylbenzenesulfonic acid.

12. The composition of claim 1, wherein an amount of the titanium etching inhibitor is in a range of about 0.01 wt % to about 20 wt %, per 100 wt % of the composition.

13. The composition of claim 1, further comprising
a solvent,
wherein the solvent comprises water.

14. The composition of claim 1, wherein
an amount of the fluorine-containing compound is in a range of about 0.005 wt % to about 0.5 wt %, per 100 wt % of the composition,
an amount of the oxidizing agent is in a range of about 0.0005 wt % to about 0.01 wt %, per 100 wt % of the composition,
an amount of the titanium etching inhibitor is in a range of about 0.1 wt % to about 3 wt %, per 100 wt % of the composition,
the fluorine-containing compound comprises HF, and
the oxidizing agent comprises HIO₄, HIO₃, NH₄IO₃, NH₄IO₄, or any combination thereof.

15. The composition of claim 1, further comprising:
a pH adjustor.

16. A cleaning method comprising:
preparing a substrate comprising a titanium-containing film and a residue; and
cleaning the titanium-containing film by using the composition of claim 1 to remove at least a portion of the residue.

17. The method of claim 16, wherein the titanium-containing film comprises:
i) titanium nitride,
ii) titanium nitride further comprising indium (In), aluminum (Al), copper (Cu), tungsten (W), cobalt (Co), lanthanum (La), scandium (Sc), gallium (Ga), zinc (Zn), hafnium (Hf), molybdenum (Mo), or any combination thereof, or
iii) a combination thereof.

18. The method of claim 16, wherein the residue comprises indium (In), aluminum (Al), copper (Cu), tungsten (W), cobalt (Co), lanthanum (La), scandium (Sc), gallium (Ga), zinc (Zn), hafnium (Hf), molybdenum (Mo), or any combination thereof.

19. The method of claim 16, wherein the titanium-containing film is substantially not etched during the cleaning.

20. A method of manufacturing a semiconductor device, the method comprising:
preparing a substrate comprising a titanium-containing film and a residue;
cleaning the titanium-containing film by using the composition of claim 1 to remove at least a portion of the residue; and
preparing a semiconductor device by performing a subsequent manufacturing process(es).
